(19) United States
(12) Patent Application Publication
(10) Pub. No.: US 2012/0224302 A1
(43) Pub. Date: Sep. 6, 2012

(54) SLIDABLE AND ROTATABLE PORTABLE ELECTRONIC DEVICE FOR ALIGNING THE SURFACES OF THE KEYPAD AND DISPLAY PORTIONS

(76) Inventor: Albert Murray Pegg, Cambridge (CA)

(21) Appl. No.: 13/040,546

(22) Filed: Mar. 4, 2011

(51) Int. Cl. H05K 7/16

(52) U.S. Cl. 361/679.01

(57) ABSTRACT

A portable electronic device, including a first portion having a first surface, a second portion having a second surface, and a slide portion, the slide portion coupled to the first and second portions. The first portion, second portion and slide portion are adapted so that the first portion can rotate between a closed position wherein the first portion at least partially covers the second surface, and a rotated position wherein the second surface is at least partially exposed and the first portion is angularly offset by a rotation angle with respect to the second portion. After being rotated into the rotated position, the first portion and slide portion can slide relative to the second portion along a second slide direction into an open position in which the first surface and second surface are aligned.

### FIELD

Embodiments herein relate to portable electronic devices, and more particularly to slidable and rotatable portable electronic devices having a display portion and keypad portion movable between a closed position and an open position.

### INTRODUCTION

Electronic devices, including portable electronic devices, have gained widespread use and may provide a variety of functions including, for example, telephonic, electronic text messaging and other personal information manager (PIM) application functions. Portable electronic devices can include mobile stations such as simple cellular phones, smart phones, Personal Digital Assistants (PDAs), tablets and laptop computers.

Some handheld devices are touch-sensitive devices having a display, such as a liquid crystal display (LCD), with a touch-sensitive overlay. These touch sensitive devices may be useful, as handheld devices tend to be small and therefore limited in space available for user input and output devices. Further, these touch-sensitive devices allow a variety of input and output configurations, for example, because the screen content on the touch-sensitive devices may change depending on the functions and operations being performed.

### BRIEF DESCRIPTION OF THE DRAWINGS

Embodiments of the present disclosure will now be described, by way of example only, with reference to the attached figures, wherein:

FIG. 1 is a simplified block diagram of components of a portable electronic device;

FIG. 2 is a front view of a portable electronic device according to one embodiment shown in a closed position;

FIG. 3 is a front view of the portable electronic device of FIG. 2 shown in an open position;

FIG. 4 is a side view of the portable electronic device of FIG. 2 shown in the closed position;

FIG. 5 is a side view of the portable electronic device of FIG. 2 shown in the open position;

FIG. 6 is a top view of the portable electronic device of FIG. 2 shown in the closed position; and

FIG. 7 is a top view of the portable electronic device of FIG. 2 shown in the open position.

### DETAILED DESCRIPTION

Described herein are various portable electronic devices that may include a touch-sensitive display disposed on a first portion, a keypad disposed on a second portion, a third portion that couples the first and second portions together, and functional components such as a memory and a processor.

It will be appreciated that for simplicity and clarity of illustration, where considered appropriate, reference numerals may be repeated among the figures to indicate corresponding or analogous elements. In addition, numerous specific details are set forth in order to provide a thorough understanding of the example embodiments described herein. However, it will be understood by those of ordinary skill in the art that the example embodiments described herein may be practiced without these specific details. In other instances, well-known methods, procedures and components have not been described in detail so as not to obscure the example embodiments described herein. Also, the description is not to be considered as limited to the scope of the example embodiments described herein.

According to one aspect, a portable electronic device, comprising a first portion having a first surface, a second portion having a second surface, and a slide portion coupled to the first and second portions, wherein the first portion, second portion and slide portion are adapted so that the first portion can rotate between a closed position wherein the first portion at least partially covers the second surface, and a rotated position wherein the second surface is at least partially exposed and the display portion is angularly offset by a rotation angle with respect to the keypad portion, and wherein, after being rotated into the rotated position, the first portion and slide portion can slide relative to the second portion along a slide direction to an open position in which the first surface and second surface are aligned.

According to another aspect, a method of opening a portable electronic device, comprising providing a first portion having a first surface, a second portion having a second surface, and a slide portion coupled to the first and second portions, rotating the first portion between a closed position wherein the first portion at least partially covers the second surface, and a rotated position wherein the second surface is at least partially exposed and the display portion is angularly offset by a rotation angle with respect to the keypad portion, and from the rotated position, sliding the first portion and slide portion relative to the second portion along a slide direction to an open position in which the first surface and second surface are aligned.

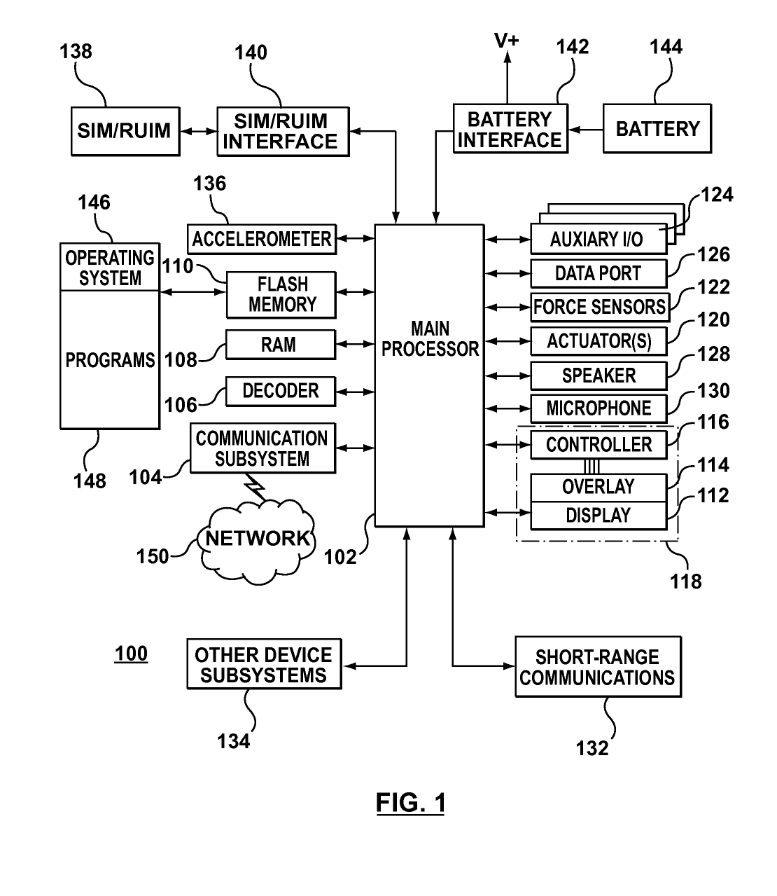

FIG. 1 shows a simplified block diagram of components of a portable electronic device 100. The portable electronic device 100 includes multiple components such as a processor 102 that controls the operations of the portable electronic device 100. Communication functions, including data communications, voice communications, or both may be performed through a communication subsystem 104. Data received by the portable electronic device 100 may be decompressed and decrypted by a decoder 106. The communication subsystem 104 may receive messages from and send messages to a wireless network 150.

The wireless network 150 may be any type of wireless network, including, but not limited to, data-centric wireless networks, voice-centric wireless networks, and dual-mode networks that support both voice and data communications.

The portable electronic device 100 may be a battery-powered device and may include a battery interface 142 as shown for receiving one or more rechargeable batteries 144.

The processor 102 also interacts with additional subsystems such as a Random Access Memory (RAM) 108, a flash memory 110, a display 112 (e.g. with a touch-sensitive overlay 114 connected to an electronic controller 116 that together comprise a touch-sensitive display 118), an actuator assembly 120, one or more optional force sensors 122, an auxiliary input/output (I/O) subsystem 124, a data port 126, a speaker 128, a microphone 130, short-range communications systems 132 and other device subsystems 134.

In some embodiments, user-interaction with the graphical user interface may be performed through the touch-sensitive overlay 114. The processor 102 may interact with the touch-sensitive overlay 114 via the electronic controller 116. Information, such as text, characters, symbols, images, icons, and other items that may be displayed or rendered on a portable electronic device may be displayed on the touch-sensitive display 118 via the processor 102.

The processor 102 may also interact with an accelerometer 136 as shown in FIG. 1. The accelerometer 136 may be utilized for detecting direction of gravitational forces or gravity-induced reaction forces.

To identify a subscriber for network access according to the present embodiment, the portable electronic device 100 may use a Subscriber Identity Module or a Removable User Identity Module (SIM/RUIM) card 138 inserted into a SIM/RUIM interface 140 for communication with a network (such as the wireless network 150). Alternatively, user identification information may be programmed into the flash memory 110 or performed using other techniques.

The portable electronic device 100 also includes an operating system 146 and software components 148 that are executed by the processor 102 and which may be stored in a persistent data storage device such as the flash memory 110. Additional applications may be loaded onto the portable electronic device 100 through the wireless network 150, the auxiliary I/O subsystem 124, the data port 126, the short-range communications subsystem 132, or any other suitable device subsystem 134.

In use, a received signal such as a text message, an e-mail message, web page download, or other data may be processed by the communication subsystem 104 and provided to the processor 102. The processor 102 then processes the received signal for output to the display 112 or alternatively to the auxiliary I/O subsystem 124. A subscriber may also compose data items, such as e-mail messages, for example, which may be transmitted over the wireless network 150 through the communication subsystem 104.

For voice communications, the overall operation of the portable electronic device 100 may be similar. The speaker 128 may output audible information converted from electrical signals, and the microphone 130 may convert audible information into electrical signals for processing and transmittal.

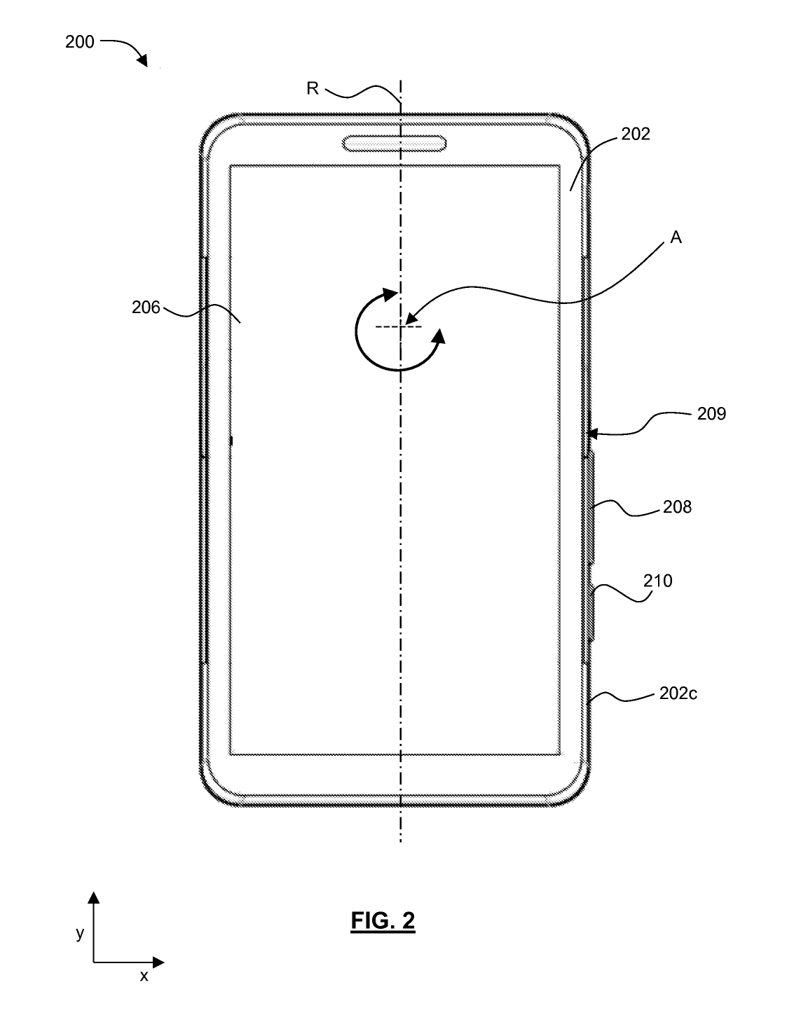

Turning now to FIGS. 2 to 7, illustrated therein is a portable electronic device 200 according to one embodiment. The portable electronic device 200 is a slidable and rotatable device and generally includes a first portion (shown here as a display portion 202), a second portion (shown here as a keypad portion 204), and a third portion (shown here as a slide portion 205) that is coupled to both the display portion 202 and keypad portion 204.

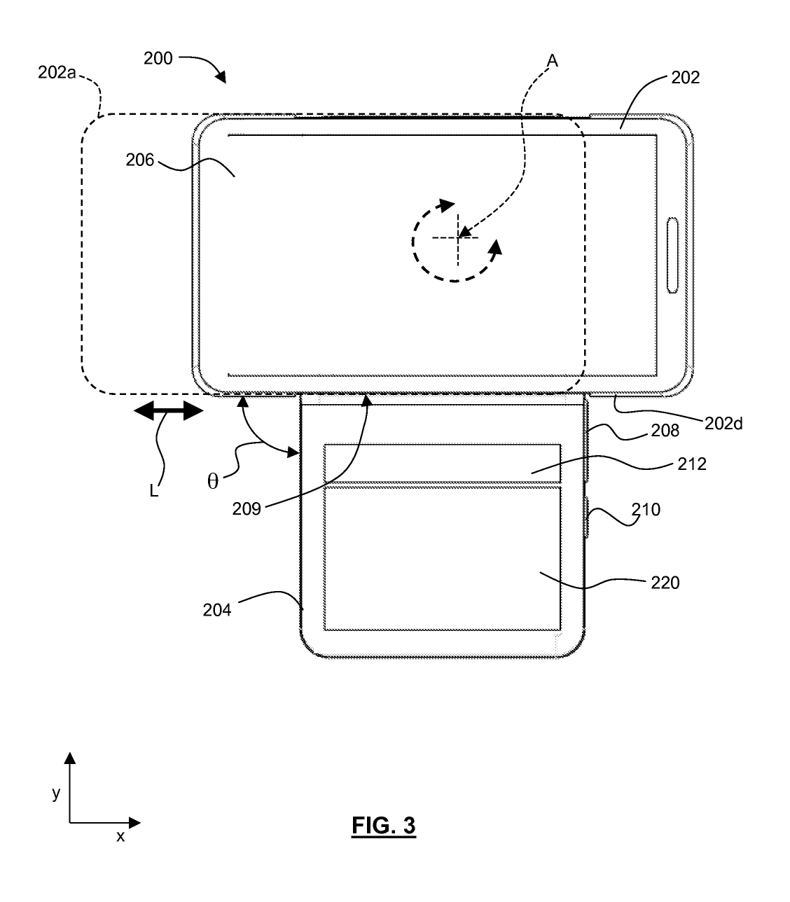

Generally the display portion 202, keypad portion 204, and slide portion 205 are sized and shaped so that the display portion 202 can move between a “closed position” (as shown in FIGS. 2, 4 and 6) and an “open position” (as shown in FIGS. 3, 5 and 7).

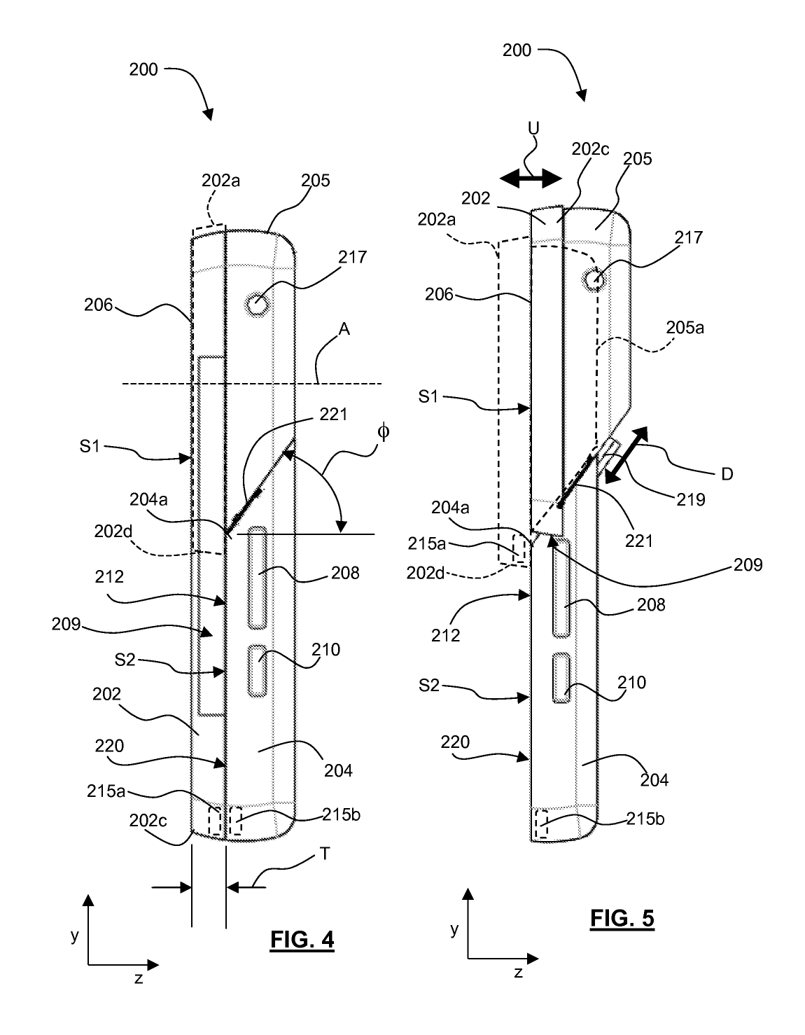

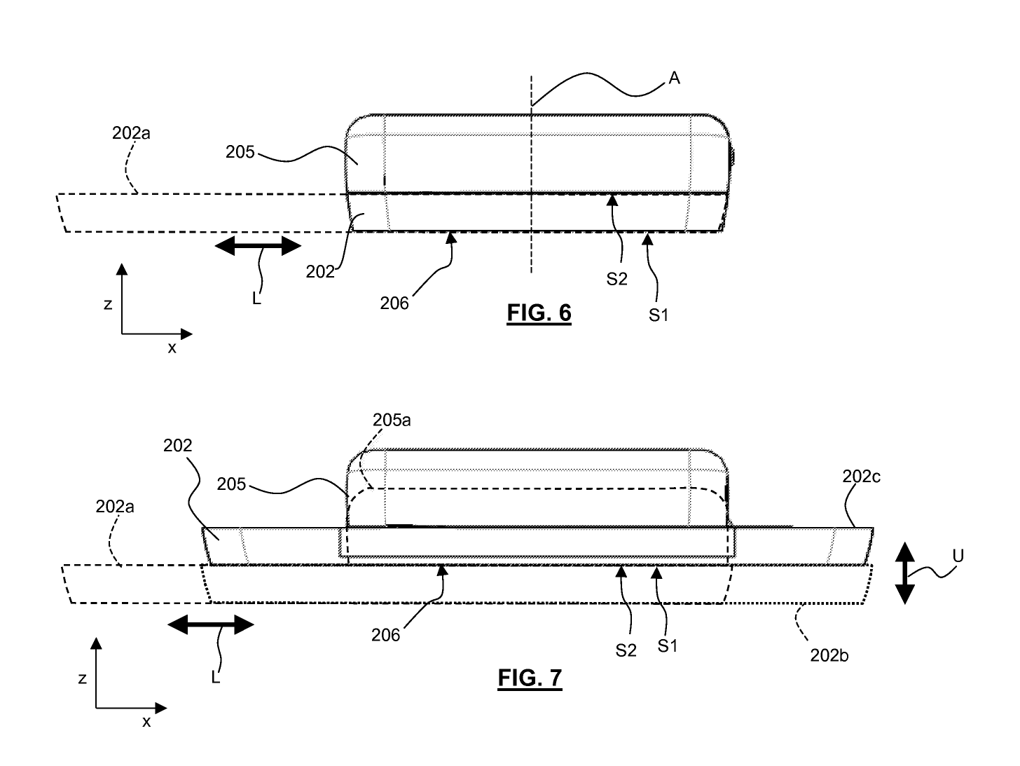

In the closed position, the display portion 202 covers at least a portion of the keypad portion 204 (e.g. the display portion 202 covers a surface S2 of the keypad portion 204 as shown in FIGS. 4 and 6). Furthermore, in the closed position, the display portion 202 is aligned with a longitudinal axis R of the portable electronic device 200.

In the open position, the surface S2 of the keypad portion 204 is exposed, and a surface S1 of the display portion 202 is aligned with the surface S2 of the keypad portion 204 (as shown in FIGS. 5 and 7) and the first surface S1 and second surface S2 are offset from each other or misaligned. Furthermore, in the open position, the display portion 202 is rotated about a rotational axis A so that the display portion 202 is angularly offset from keypad portion 204 and the first surface S1 and second surface S2 are still offset. For example, in the open position, the display portion 202 may be perpendicular to the longitudinal axis R (as shown in FIGS. 3, 5 and 7).

In particular, the slide portion 205 and display portion 202 are rotatably coupled so that the display portion 202 may be rotated from the closed position (shown in FIG. 2) to a “rotated position” (indicated generally as 202a in FIG. 3) wherein the keypad portion 204 is at least partially exposed.

Furthermore, the slide portion 205 and display portion 202 are slidably coupled so that, once in the rotated position 202a, the display portion 202 can slide along a first slide direction L (e.g. perpendicular to longitudinal axis R of the device 200) to a “slide position” (indicated generally as 202b in FIG. 7, and with the corresponding position of the slide portion 205 indicated generally as 205a). For example, in the slide position 202b, the display portion 202 is generally centered above the keypad portion 204.

Furthermore, the slide portion 205 is slidably coupled to the keypad portion 204 so that when the display portion 202 is in the slide position 202b, the display portion 202 and slide portion 205 can slide in a second slide direction D to the open position (indicated generally as 202c in FIG. 7) so that the surface S1 of the display portion 202 and the surface S2 of the keypad portion 204 can be aligned (as shown in FIG. 5). In effect, the display portion 202 may be “dropped down” from the slide position 202a (e.g. along the z-direction) so that the two surfaces S1 and S2 align or are generally coplanar.

Referring now to FIGS. 2 and 3, the display portion 202 and slide portion 205 are rotatably coupled so that the display portion 202 rotates about the rotation axis A with respect to the keypad portion 202 by a rotation angle θ when moving from the closed position to the rotated position 202a.

In this embodiment, the rotation angle θ is selected so that the display portion 202 is generally aligned with the longitudinal axis R in the closed position (shown in FIG. 2), and then the display portion 202 is generally perpendicular to the longitudinal axis R in the rotated position 202a (shown in FIG. 3). In particular, in this embodiment the rotation angle θ is about 90 degrees.

In other embodiments, the display portion 202 may be rotatably coupled to the slide portion 205 in other ways. In particular, the rotation axis A may have other locations and the rotation angle θ may be another angle. For example, the rotation angle θ may be larger or smaller than 90 degrees.

Referring now to FIGS. 4 and 5, the second slide direction D has a component that extends in a direction that is normal to the surface S1 of the display portion 202 (e.g. in a normal direction U generally along the z-axis). As shown, the slide direction D may be angularly offset upwards from the normal direction U by a slide angle φ (as shown in FIG. 4), which in some embodiments may be greater than zero.

Accordingly, as the display portion 202 and slide portion 205 move in the second slide direction D, the display portion 202 and slide portion 205 will move along both the normal direction U (e.g. the z-axis) by an amount proportional to the cosine of the slide angle φ, and along a direction aligned with the longitudinal axis R (e.g. the y-axis) by an amount proportional to the sine of the slide angle φ. Generally, the second slide direction D can be described as having a component aligned with the longitudinal axis R (e.g. the y-component) and another component in the normal direction U (e.g. the z-component).

Selecting a slide angle φ greater than zero may allow for easier mechanical coupling between the display portion 202, the keypad portion 204, and the slide portion 205. Furthermore, when the slide angle φ is greater than zero, an upward force on the display portion 202 (e.g. a user's thumb or finger pushing on the display portion 202 towards a top end of the device 200) when the display portion 202 is in the slide position 202b will tend to push the display portion 202 in the second slide direction D. This may make it easier for a user to fully open the portable electronic device 200.

In some embodiments, the slide angle φ may be between 15 degrees and 75 degrees. In some embodiments, the slide angle φ may be between 30 degrees and 60 degrees. In some embodiments, the slide angle φ may be approximately 45 degrees.

In other embodiments, the slide angle φ may be less than zero (e.g. the slide angle φ may be negative).

As shown in FIG. 4, the display portion 202 has a thickness T. Accordingly, when moving the display portion 202 from the slide position 202b to the open position 202c (e.g. to align the first and second surfaces 51 and S2), the slide portion 205 moves along the normal direction U by a distance approximately equal to T. This means that the slide portion 205 should be moved in the second slide direction D by distance equal to the distance T divided by the cosine of the slide angle φ.

The display portion 202, keypad portion 204 and slide portion 205 may be coupled together according to various techniques. For example, the keypad portion 202 and slide portion 205 may be rotatably coupled together so as to rotate about the rotation axis A. The position of rotation axis A is generally offset from the display portion 202 by a distance selected so that when the display portion 202 is in the rotated position 202a, the surface S2 of the keypad portion 204 is exposed and the display portion 202 can be moved with the slide portion 205 in the slide direction D.

In some embodiments, the display portion 202 can be moved from the rotated position 202a in the first slide direction L into the slide position 202b. Once in the slide position 202b, the display portion 202 and slide portion 205 can then be slid along the second slide direction D (with at least a component aligned in the normal direction R) into the open position 202c (as shown for example in FIG. 7).

In other embodiments the display portion 202 can be moved directly from the rotated position 202a to the open position 202c wherein the surfaces S1 and S2 are aligned (and generally without the display portion 202 sliding in the first slide direction L into the slide position 202b). For example, in some embodiments, the display portion may move directly from the rotated position 202a along the second slide direction D to the open position, in which case the display portion 202 may not be centered above the keypad portion 204 in the open position.

In other embodiments, the rotation axis A may be selected so that the display portion 202 is centered above the keypad portion 204 when the display portion 202 is in the rotated position. More particularly, the rotation axis A may be offset to the left or right of the longitudinal axis R (as viewed in FIGS. 2 and 3) by a lateral offset distance. The lateral offset distance may be selected so that rotating the display portion 202 from the closed position to the rotated position 202a results in the display portion 202 being centered above the keypad portion 204 in the rotated position.

The slide portion 205 and keypad portion 204 may be slidably coupled together via a slide mechanism 219, which may include interlocking slide rails for example. The slide mechanism 219 allows for relative movement between the slide portion 205 and the keypad portion 204 along the slide direction D so that the surfaces S1 and S2 of the display portion and keypad portion 204 can be aligned, but inhibits movement in other directions. In this embodiment, the slide mechanism 219 is inclined upwardly (from front to back of the device 200) so as to define the slide angle φ.

In some embodiments, the slide mechanism 219 may have other configurations, for example, a tongue in groove arrangement that allows sliding movement between the keyboard portion 204 and the slide portion 205.

Similarly, the slide portion 205 and display portion 202 may be slidably coupled together by a slide mechanism, which could include interlocking rails for example.

In some embodiments, the slide mechanisms may include one or more biasing members (e.g. a linear spring, such as a compression or extension spring, or another biasing member). Furthermore, a biasing member (e.g. a coiled spring) may be provided between the display portion 202 and the slide portion 205 to facilitate rotation between the closed position and the rotated position.

The biasing members may be used to encourage at least one of the slide portion 205 and display portion 202 to move between one or more of the open position, the rotated position, the slide position, and the closed position. For example, a linear spring 221 in the slide mechanism 219 may be compressed when the portable electronic device 200 is in the closed position (see FIG. 4) and extended when the portable electronic device 200 is in the open position (see FIG. 5). Similarly, a coiled spring may be configured to encourage rotation of the display portion 202 from the closed position to the rotated position.

In some embodiments, one or more locks or latches (e.g. mechanical locks, magnets, etc.) may be provided in one or more of the display portion 202, keypad portion 204 and slide portion 205 to help retain the portable electronic device in one or more of the closed position, the rotated position and the open position. For example, as shown in FIGS. 4 and 5, magnets 215a, 215b in the display portion 202 and the keypad portion 204 (respectively) may attract each other and help retain the device 200 in the closed position, but may not substantially interact with each other when the device 200 is in the open position.

When moving the display portion 202 from the closed position (shown in FIG. 2) to the open position 202c, a user may first rotate the display portion 202 around the rotation axis A so that the display portion 202 is in the rotated position 202a. In some embodiments, this movement may be facilitated by a biasing member (e.g. a spring). From the rotated position 202a, the display portion 202 can then slide along the first slide direction L to the slide position 202b. The display portion 202 can then be moved in the second slide direction D into the open position 202c wherein the surfaces S1 and S2 are aligned.

In some embodiments, the user may push upwardly on the display portion 202 (when in the slide position 202b) so as to slide the display portion 202 and the slide portion 205 in the second slide direction D. In some embodiments, a biasing member (e.g. a spring) may at least partially bias the slide portion 205 along the second slide direction D to the open position 202c. Once in the open position 202c, in some embodiments a locking mechanism (e.g. a latch or magnet) may help retain the portable electronic device 200 in the open position.

In some embodiments, a side edge 202d of the display portion 202 may include a recessed portion 209 (as shown in FIG. 2) adapted to facilitate clearance of the display portion 202 past the corner 204a of the keypad portion 204 when the device 200 is in the slide position 202b.

When the user wants to move the portable electronic device 200 back to the closed position (e.g. to close the portable electronic device 200), the user may press the back of the slide portion 205, moving the display portion 202 and slide portion 205 back along the second slide direction D back to the slide position 202b, then slide the display portion 202 back along the first slide direction L to the rotated position 202a, and then rotate the display portion 202 about the rotation axis A to cover the keypad portion 204 (in the closed position). In some embodiments, one or more biasing members (e.g. springs) may help facilitate closing of the portable electronic device 200, and one or more locks may be used to help retain the portable electronic device 200 in the closed position.

In some embodiments, the first and second surfaces S1 and S2 are “active” surfaces in that they may include one or more input or output devices (or both), such as display screens, buttons, etc. For example, the first surface S1 might include the surface of a touch screen display 206. Similarly, the second surface S2 might include the surface of a keypad 220, other input devices 212 or another portion of the keypad portion 204.

Aligning the “active” surfaces S1 and S2 when the portable electronic device 200 is in the open position may be beneficial. For example, user interaction with the portable electronic device 200 may be improved as a user may be able to transition from engaging the first surface S1 (e.g. touching the touch screen display 206 using a finger), to engaging the second surface S2 (e.g. the input devices 212 or keypad 220) generally without encountering discontinuities, such as a lip or stepped portion between the surfaces.

While the portable electronic device 200 has been described with respect to a touch screen display 206 and a keypad 220, the portable electronic device 200 may include other input and output devices, and may have other configurations as will be appreciated from the following description of some other exemplary input and output devices.

In some embodiments, the display 206 could be an LCD display with touch screen capabilities. For example, the display 206 could be the display 118 as generally described above. In some other embodiments, the display 206 may not be a touch screen display.

The portable electronic device 200 may include other input devices, such as navigation keys or buttons, a physical or virtual keyboard, a trackpad, a trackball, multimedia keys, etc. For example, in this embodiment, the keypad portion 204 includes one or more input devices 212, which could include an optical navigation module (e.g. a trackpad), buttons, such as a phone application button, a home screen button, etc. In some embodiments, these input devices may include optical sensors, mechanical buttons, “soft keys”, or various combinations thereof.

In some embodiments, the keypad portion 204 includes physical buttons 208 and 210 on a side of the keypad portion 204. In some embodiments, buttons 208, 210 could be used for navigation, volume control, or for other purposes. The portable electronic device 200 as shown also includes an audio jack 217 on the side of the slide portion 205, which may be used to couple the portable electronic device 200 to a speaker, a microphone, etc. In some embodiments, the slide portion may include other input and output devices.

In some embodiments, the keypad 220 may include a plurality of alphanumeric keys for inputting data into and otherwise controlling the portable electronic device 200. In some embodiments, the keys may represent an alphabet and may be arranged with a standard keyboard layout (e.g. QWERTY, QWERTZ, DVORAK, etc.) or according to other particular patterns. In some embodiments, the keypad 220 could be a physical keypad 220 with mechanical keys. In other embodiments, the keypad 220 could be a touchscreen with soft keys.

As shown in FIGS. 3 and 5, when the portable electronic device 200 is in the open position, the keypad 220 on the keypad portion 204 may be exposed for user access. As shown in FIGS. 2 and 4, when the portable electronic device 200 is in the closed position, the keypad 220 may be covered by the display portion 202. This may be beneficial as it may protect the keypad 220 when not in use, and may also inhibit keys from being pressed unintentionally when a user is carrying the portable electronic device 200 (e.g. in a pocket).

In some embodiments (e.g. when the display 206 is a touchsceen), the user may be able to perform functions on the portable electronic device 200 when the device 200 is in the closed position, for example, by interacting with the accessible input devices (e.g. buttons 208, 210, the touch screen display 206, etc.). Then, when the device 200 is in the open position, functions can be performed using additional input devices, such as the input devices 212 and keypad 220.

While reference has been made herein to portable electronic devices wherein a first portion is a display portion, a second portion is a keypad portion, and a third portion is a slide portion, this is not meant to be limiting and other configurations are possible. For example, the first portion and second portion may both be touchscreen portions with no keypad. In other examples, the first portion may have a keypad and the second portion may include a display.

Furthermore, while in some embodiments described herein the display portion 202 is rotated into the rotated position 202a before sliding into the slide position 202b, in other embodiments, the display portion 202 may slide relative to the slide portion 205 before being rotated about the rotation axis A.

Furthermore, in some embodiments as described herein, the display portion 202 is generally centered above the keypad portion 204 in the slide position 202b and the open position 202c, meaning that the midline of the display portion 202 is aligned with the midline of the keypad portion 204. This may provide for a desired user interface, for instance as the display 206 may be centered above the keypad 220 which may make reading text on the display 206 easier.

In other embodiments, the midlines of the display portion 202 and keypad portion 204 may be offset when the display portion 202 is in the slide position 202b and the open position 202c. In particular, in some embodiments the display portion 202 can be moved directly from the rotated position 202a to an open position 202c wherein the surfaces S1 and S2 are aligned (and generally without the display portion 202 sliding in the first slide direction L).

Furthermore, in some other embodiments, the display portion 202 may be slid in the first slide direction L after being slid in the second slide direction D. For example, the display portion 202 may be rotated by the rotation angle θ, then moved along the second slide direction D (e.g. so that the surfaces S1 and S2 are aligned), and then moved along the first slide direction L (e.g. to align the midlines of the display portion 202 and the keypad portion 204).

While the above description provides examples of one or more processes or apparatuses, it will be appreciated that other processes or apparatuses may be within the scope of the accompanying claims.

1. A portable electronic device, comprising:
a first portion having a first surface;
a second portion having a second surface; and
a slide portion coupled to the first and second portions;
wherein the first portion, second portion and slide portion are adapted so that the first portion can rotate between a closed position wherein the first portion at least partially covers the second surface, and a rotated position wherein the second surface is at least partially exposed and the first portion is angularly offset by a rotation angle with respect to the second portion, and wherein, after being rotated into the rotated position, the first portion and slide portion can slide relative to the second portion along a second slide direction to an open position in which the first surface and second surface are aligned.

2. The portable electronic device of claim 1, wherein, when the first portion is in the rotated position, the first portion can slide relative to the slide portion along a first slide direction to a slide position.

3. The portable electronic device of claim 1, wherein the first portion is slidable into a slide position before being slid to the open position.

4. The portable electronic device of claim 2, wherein when the first portion is in the slide position, the first portion is centered above the second portion.

5. The portable electronic device of claim 1, wherein the rotation angle is 90 degrees.

6. The portable electronic device of claim 1, wherein the first portion is a display portion and includes a display.

7. The portable electronic device of claim 1, wherein the second portion is a keypad portion and includes a keypad.

8. The portable electronic device of claim 2, wherein the first slide direction is transverse to a longitudinal direction of the portable electronic device.

9. The portable electronic device of claim 1, wherein the second slide direction has a component normal to the first surface.

10. The portable electronic device of claim 1 wherein the second slide direction is inclined upwardly by a slide angle and has a component aligned with a longitudinal axis of the portable electronic device.

11. The portable electronic device of claim 10, wherein the slide angle is between 15 and 75 degrees

12. The portable electronic device of claim 10, wherein the slide angle is between 30 and 60 degrees.

13. The portable electronic device of claim 10, wherein the second portion and slide portion are slidably coupled together using a slide mechanism inclined along the slide angle.

14. The portable electronic device of claim 1, further comprising at least one biasing member for biasing the portable electronic device to at least one of the closed position, the rotated position, and the open position.

15. The portable electronic device of claim 14, wherein the at least one biasing member includes a spring.

16. The portable electronic device of claim 1, further comprising at least one locking member for retaining the portable electronic device in at least one of the closed position, the rotated position, and the open position.

17. The portable electronic device of claim 16, wherein the at least one locking member includes at least one magnet.

18. The portable electronic device of claim 1 wherein a side edge of the first portion includes a recessed portion adapted to facilitate movement of the first portion in the second slide direction.

19. A portable electronic device, comprising:
a first portion having a first surface;
a second portion having a second surface; and
a slide portion coupled to the first and second portions;
wherein the first portion, second portion and slide portion are adapted so that the first portion can rotate between a closed position wherein the first portion at least partially covers the second surface, and a rotated position wherein the second surface is at least partially exposed and the first portion is angularly offset by a rotation angle with respect to the second portion, wherein, when the first portion is in the rotated position, the first portion can slide relative to the slide portion along a first slide direction to a slide position, and wherein, after being rotated into the rotated position, the first portion and slide portion can slide relative to the second portion along a second slide direction to an open position in which the first surface and second surface are aligned.

20. A method of opening a portable electronic device, comprising:
providing a first portion having a first surface, a second portion having a second surface, and a slide portion coupled to the first and second portions;
rotating the first portion between a closed position wherein the first portion at least partially covers the second surface, and a rotated position wherein the second surface is at least partially exposed and the first portion is angularly offset by a rotation angle with respect to the second portion; and
from the rotated position, sliding the first portion and slide portion relative to the second portion along a second slide direction to an open position in which the first surface and second surface are aligned.
